(19) United States
(12) Patent Application Publication
(10) Pub. No.: US 2024/0239648 A1
(43) Pub. Date: Jul. 18, 2024

(54) MEMS DEVICE HAVING AN IMPROVED CAP AND MANUFACTURING PROCESS THEREOF

(71) Applicant: STMICROELECTRONICS S.r.l., Agrate Brianza (IT)

(72) Inventors: Silvia NICOLI, Briosco (IT); Lorenzo TENTORI, Verano Brianza (IT); Giuseppe BRUNO, Paterno' (IT)

(73) Assignee: STMICROELECTRONICS S.r.l., Agrate Brianza (IT)

(21) Appl. No.: 18/409,584

(22) Filed: Jan. 10, 2024

(30) Foreign Application Priority Data
Jan. 17, 2023 (IT) 102023000000585

(51) Int. Cl. B81B 7/00; B81C 1/00

(52) U.S. Cl. CPC B81B 7/0067; B81C 1/00317; B81B 2201/0292; B81B 2203/0315; B81C 2203/0118; B81C 2203/0127

(57) ABSTRACT

The MEMS device has: a sensor body having a functional structure configured to transduce a physical or chemical quantity into a corresponding electrical quantity; and a cap bonded to the sensor body and having a first cavity overlying the functional structure. The cap has a supporting portion and a cover portion that form the first cavity. The supporting portion is bonded to the sensor body. The cover portion is bonded to the supporting portion and has an inner wall delimiting on a side the first cavity and facing the functional structure. The MEMS device further has a first coating that extends within the first cavity on the inner wall of the cover portion.

### BACKGROUND

### Technical Field

The present disclosure relates to a MEMS device having an improved cap and to a corresponding manufacturing process.

### Description of the Related Art

As is known, MEMS devices comprise a functional structure configured to transduce a physical quantity, for example an electromagnetic radiation or an acceleration, into a corresponding electrical signal.

Moreover, MEMS devices are known that have a cap, which forms part of the corresponding packaging, which is useful for example to protect the functional structure of the MEMS device.

The cap of known MEMS devices is of a monolithic type and comprises a cavity that overlies the functional structure. In detail, the cap comprises an inner wall that upwardly delimits the cavity and faces the functional structure.

The distance between the inner wall and the functional structure affects the operating properties of the MEMS device, for example it affects the FoV (Field of View) of a MEMS device based upon TMOS (Thermal Metal-Oxide-Semiconductor) technology for detection of an infrared radiation.

Consequently, the possibility of regulating said distance enables adaptation of the MEMS device to different applications.

However, the present applicant has noted that, in known MEMS devices, the possibility of regulating the aforesaid distance at the design stage is not sufficient for specific applications.

### BRIEF SUMMARY

The present disclosure is directed to embodiments to overcome the disadvantages of the prior art. Consequently, according to the present disclosure a MEMS device and a corresponding manufacturing process are provided.

For example, in at least one embodiment of a MEMS device of the present disclosure, the embodiment of the MEMS device may be summarized as including: a sensor body comprising a functional structure configured to transduce a physical or chemical quantity into a corresponding electrical quantity; a cap bonded to the sensor body and having a first cavity overlying the functional structure, wherein the cap comprises a supporting portion and a cover portion that form the first cavity, the supporting portion being bonded to the sensor body, the cover portion being bonded to the supporting portion and having an inner wall delimiting on a side the first cavity and facing the functional structure; and a first coating extending within the first cavity on the inner wall of the cover portion.

### BRIEF DESCRIPTION OF THE SEVERAL VIEWS OF THE DRAWINGS

For a better understanding of the present disclosure, some embodiments thereof are now described purely by way of non-limiting example, with reference to the attached drawings, wherein:

FIG. 1 is a cross-sectional view of the present MEMS device, according to one embodiment;

FIGS. 2-17 are cross-sectional views of the MEMS device of FIG. 1, in successive manufacturing steps, according to a manufacturing process;

FIGS. 18-25 are cross-sectional views of the MEMS device of FIG. 1, in successive manufacturing steps, according to a different manufacturing process;

FIG. 26 is a cross-sectional view of the present MEMS device, according to a different embodiment; and

FIG. 27 is a cross-sectional view of the present MEMS device, according to a further embodiment.

### DETAILED DESCRIPTION

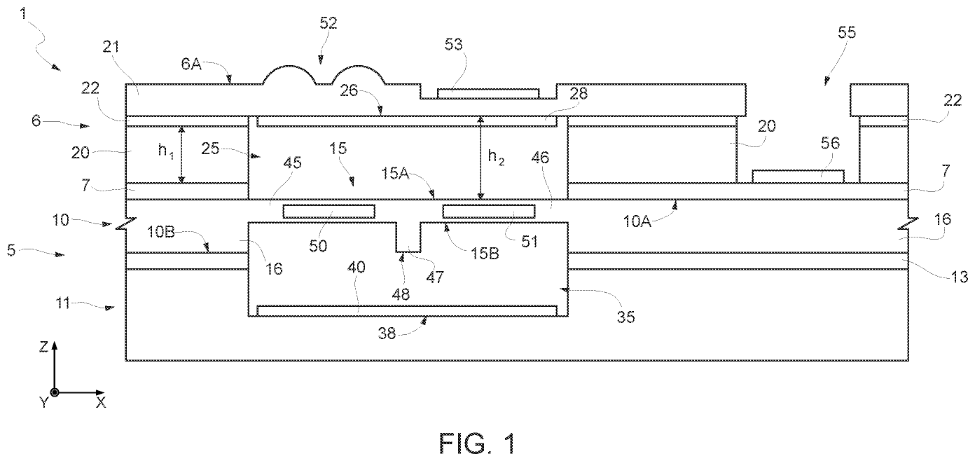

FIG. 1 shows a MEMS device, in particular here an infrared sensor based on TMOS technology, referred to hereinafter as TMOS device 1, in a cartesian reference system XYZ comprising a first axis X, a second axis Y, and a third axis Z.

The TMOS device 1 is obtained via micromachining techniques for machining semiconductor materials, such as silicon.

The TMOS device 1 comprises a sensor body 5 and a cap 6, which has a top surface 6A based on the orientation as shown in FIG. 1 and is bonded to the sensor body 5 via a first bonding region 7. The top surface 6A may be referred to as a respective surface of the cap 6.

The first bonding region 7 maybe a single-layer or multilayer region, for example insulating, for example formed by one or more layers of oxide, in particular here of glass frit.

The sensor body 5 comprises a device substrate 10 having a top surface 10A and a bottom surface 10B based on the orientation as shown in FIG. 1, and a support substrate 11 bonded to the bottom surface 10B of the device substrate 10 via a second bonding region 13. The bottom surface 10B may be referred to as a surface of a respective surface of the device substrate.

The second bonding region 13 maybe a single-layer or multilayer region, for example insulating, for example formed by one or more layers of oxide, in particular of glass frit.

In detail, the device substrate 10 comprises a functional structure 15 and a peripheral structure 16, coupled together.

The peripheral structure 16 forms the first and the second surfaces 10A, 10B of the device substrate 10.

The cap 6 is bonded to the first surface 10A of the device substrate 10.

The functional structure 15 is configured to generate one or more electrical signals as a function of an incident infrared radiation, as discussed in greater detail hereinafter.

The functional structure 15 has a top surface 15A. In the embodiment illustrated, the top surface 15A is flush with the top surface 10A of the peripheral structure 16; however, the top surface 15A may be at a different height, parallel to the third axis Z, with respect to the top surface 10A, according to the specific application. The functional structure includes a bottom surface 15B opposite to the top surface 15A. The top surface 15A may be referred to as a first surface and the bottom surface 15B may be referred to as a second surface.

In detail, the cap 6 comprises a supporting substrate 20, of semiconductor material, for example silicon, bonded to the sensor body 5, and a cover substrate 21, of semiconductor material, for example silicon, bonded to the supporting substrate 20 and forming the top surface 6A of the cap 6.

The supporting substrate 20 has a thickness h₁, along the third axis Z, comprised for example between 40 μm and 200 μm.

A third bonding region 22 extends between the supporting substrate 20 and the cover substrate 21.

The third bonding region 22 maybe a single-layer or multilayer region, for example insulating, for example formed by one or more oxide layers or of glass frit.

In the embodiment illustrated, the third bonding region 22 is a layer of oxide, for example silicon oxide.

The third bonding region 22 has a thickness, along the third axis Z, comprised for example between 0.5 μm and 2 μm.

The cap 6 comprises a top cavity 25 that overlies the functional structure 15 of the sensor body 5.

In this embodiment, the supporting substrate 20 and the third bonding region 22 delimit the top cavity 25 laterally.

The cover substrate 21 has an inner wall 26 that delimits the top cavity 25 upwardly. In practice, the inner wall 26 faces the top surface 15A of the functional structure 15.

In detail, the inner wall 26 is arranged at a distance h₂, parallel to the third axis Z, from the functional structure 15, for example greater than 40 μm, in particular comprised between 40 μm and 200 μm.

In practice, the distance h₂ is measured between the inner wall 26 and the top surface 15A of the functional structure 15.

The distance h₂ may substantially correspond to the thickness h₁ of the supporting substrate 20. In fact, the thickness along the third axis Z of the first insulating region 7 and of the third insulating region 22 maybe much smaller than the thickness h₁ of the supporting substrate 20.

The cap 6 further comprises a top coating 28, which extends on the inner wall 26, within the top cavity 25.

The top coating 28 is a region configured to prevent reflection of an incident electromagnetic radiation, in particular here an infrared radiation. In practice, the top coating 28 is an antireflective coating.

The top coating 28 maybe a single-layer or multilayer region, for example comprising one or more layers of: silicon oxide, aluminum oxide, zinc sulphide, hafnium, nitride oxide, etc.

The top coating 28 may have a thickness, parallel to the third axis Z, comprised for example between 0.5 μm and 2 μm.

The top coating 28 has a width, along the first axis X, substantially equal to the width, along the first axis X, of the inner wall 26 and of the functional structure 15.

Furthermore, albeit not illustrated herein, the top coating 28 has a width, along the second axis Y, substantially equal to the width, along the second axis Y, of the inner wall 26 and of the functional structure 15.

In practice, the top coating 28 substantially faces the entire top surface 15A of the functional structure 15. In other words, in some embodiments, the top coating 28 may overlap a majority of the functional structure 15, may fully overlap the functional structure 15, or may fully overlap at least the sensitive regions 50, 51 of the functional structure 15.

The sensor body 5 comprises a bottom cavity 35 arranged on an opposite side of the functional structure 15 with respect to the top cavity 25.

In other words, the bottom cavity 35 is arranged underneath the functional structure 15.

In practice, the functional structure 15 is suspended between the top cavity 25 and the bottom cavity 35.

In this embodiment, the bottom cavity 35 and the top cavity 25 are in communication with one another, for example via openings through the functional structure 15, here not illustrated. In practice, the bottom cavity 35 and the top cavity 25 form a single chamber, in particular here of a hermetic type, isolated from the outside of the TMOS device 1.

In detail, the bottom cavity 35 extends partially through the second bonding region 13 and the support substrate 11.

Furthermore, in this embodiment, the bottom cavity 35 extends partially also through the device substrate 10.

The support substrate 11 has an inner wall 38 that delimits the bottom cavity 35 downward; i.e., the inner wall 38 faces the functional structure 15.

The sensor body 5 comprises a bottom coating 40 extending on the inner wall 38, within the bottom cavity 35.

The bottom coating 40 is a getter region, i.e., of reactive material, for example formed by one or more metals, designed to adsorb or react with gaseous species present in the chamber formed by the top cavity 25 and the bottom cavity 35. In practice, the bottom coating 40 is configured to increase the level of vacuum of the chamber formed by the top cavity 25 and the bottom cavity 35.

The bottom coating 40 may have a thickness, parallel to the third axis Z, comprised for example between 0.5 μm and 2 μm.

The bottom coating 40 has a width, along the first axis X, substantially equal to the width, along the first axis X, of the inner wall 38 and of the functional structure 15.

Moreover, albeit not illustrated herein, the bottom coating 40 has a width, along the second axis Y, substantially equal to the width, along the second axis Y, of the inner wall 38 and of the functional structure 15.

The functional structure 15 maybe formed by one or more layers or subregions, for example of oxide, conductive and/or semiconductive material, configured to generate electrical signals in response to the reception of an electromagnetic radiation, in particular in the infrared frequency range.

In detail, the functional structure 15 comprises a detection region 45 and a reference region 46, coupled to the peripheral structure 16 and arranged staggered to one another parallel to the first axis X.

The functional structure 15 further comprises a coupling region 47 that extends, parallel to the first axis X, between the detection region 45 and the reference region 46. The coupling region has an end surface 48 that is spaced outward from the bottom surface 15B of the functional structure 15.

The detection region 45 and the reference region 46 have a thickness, along the third axis Z, smaller than the thickness, along the third axis Z, of the coupling region 47.

In this embodiment, the coupling region 47 is coupled, in a way here not illustrated, also to the peripheral structure 16.

In practice, the detection region 45 and the reference region 46 are suspended regions of the functional structure 15, and the coupling region 47 is a support region of the functional structure 15.

The detection region 45 and the reference region 46 each comprise a respective active region 50, 51, which is sensitive to the electromagnetic radiation, in particular in the infrared frequency range. The sensitive regions 50, 51 maybe the same as or different from one another, in particular equal to one another, according to the specific application. In some embodiments, the sensitive regions 50, 51 may be equal in size and shape to each other.

For instance, the active regions 50, 51 may each be formed by a respective array of elements sensitive to temperature changes induced by infrared radiation; in particular, in the present example, the sensitive elements are formed by corresponding suspended MOSFETs (not illustrated) that operate below threshold.

In this embodiment, the TMOS device 1 comprises one or more lenses, of which two lenses 52 are illustrated in FIG. 1, arranged on the cap 6 and configured to focus an infrared radiation incident on the top surface 6A of the cap onto the sensitive region 50 of the detection region 45.

In detail, the lenses 52 are lenses formed on the top surface 6A of the cap, starting from the material of the cover substrate 21, for example of semiconductive material, in particular here of silicon.

The lenses 52 are arranged along and at the top surface 6A of the cap 6, and are aligned with the detection region 45 parallel to the third axis Z.

The TMOS device 1 further comprises a shielding region 53, for example of metallic material, which extends on the top surface 6A of the cap 6 and is aligned with the reference region 46 parallel to the third axis Z.

The shielding region 53 is configured to absorb and/or reflect an electromagnetic radiation, in particular in the infrared frequency range, incident on the top surface 6A of the cap 6.

In detail, in this embodiment, the shielding region 53 extends within a recess formed in the cover substrate 21.

The cap 6 further comprises an opening 55 that extends through the cover substrate 21, the third bonding region 22 and the supporting substrate 20, thereby exposing a portion of the first bonding region 7.

The opening 55 is arranged staggered laterally, here parallel to the first axis X, with respect to the top cavity 25.

One or more conductive pads 56, one of which is illustrated in FIG. 1, extend, within the opening 55, on the exposed portion of the first bonding region 7.

The conductive pad 56 is connected to the active regions 50, 51 via one or more conductive tracks, here not illustrated, and can be used for the electrical connection of the TMOS device 1 to an external circuit (here not illustrated), for example an external reading circuit. For instance, the conductive pad 56 maybe connected to the external circuit via wire-bonding extending through the opening 55.

In use, the TMOS device 1 maybe used for detecting the electromagnetic radiation, in particular in the infrared frequency range, incoming from the outside of the TMOS device 1 and incident on the top surface 6A of the cap 6.

For instance, the TMOS device 1 can detect the incident infrared radiation and be used as temperature sensor or as presence detector.

The portion of electromagnetic radiation incident on the shielding region 53 is shielded. The portion of electromagnetic radiation incident on the lenses 52 is focused onto the detection region 45.

Therefore, in use, the sensitive region 51 of the reference region 46 can generate electrical signals indicative of a background radiation, irrespective of the electromagnetic radiation incident on the cap 6. Instead, the sensitive region 50 of the detection region 45 can generate electrical signals indicative of the intensity of the incident electromagnetic radiation.

In practice, the electrical signals generated by the reference region 46 can be used as reference in a subsequent elaboration step, for example to compensate for possible variations of the electrical signals generated by the sensitive region 50 of the detection region 45 and caused by temperature changes independent of the infrared radiation. In other words, the signals generated by the sensitive region 51 of the reference region 46 can be used to carry out a differential reading of the incident radiation.

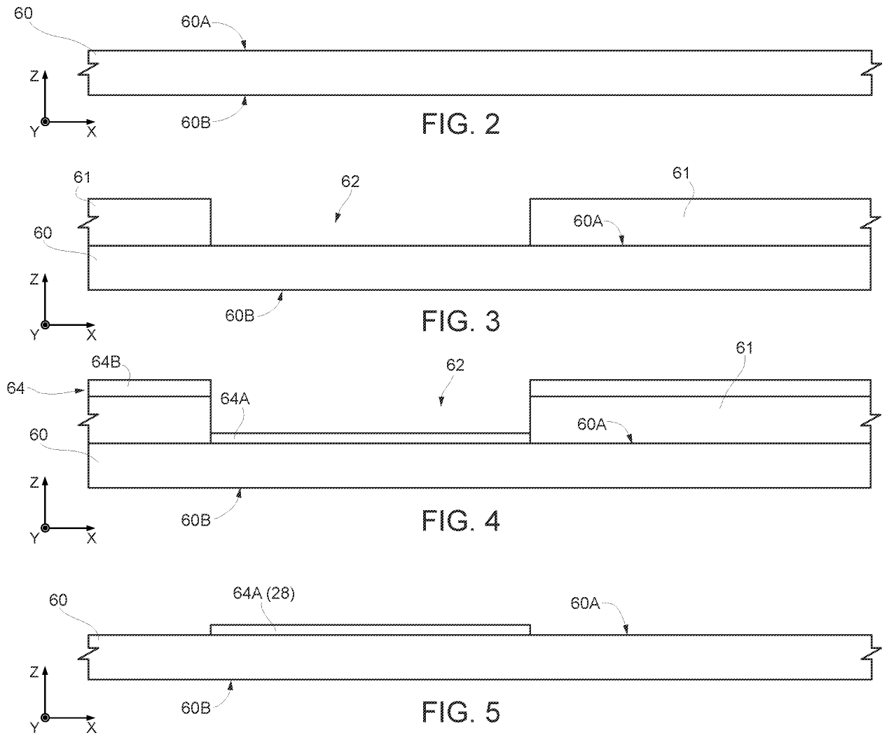

In the present TMOS device 1, the fact that the cap 6 is formed by two substrates (a supporting substrate 20 and a cover substrate 21) bonded together bestows a high versatility of design of the cap 6, as also discussed hereinafter in regard to the manufacturing process described with reference to FIGS. 2-17 and 18-25.

In detail, this makes it possible to regulate the distance h₂ between the inner wall 26 and the functional structure 15, according to the specific application. In particular, by modifying the distance h₂, it is possible to modify the FoV (Field of View) of the TMOS device 1.

In the TMOS device 1, the distance h₂ may be great, for example, greater than 40 μm. A high value of the distance h₂ makes it possible to obtain low values of FoV, for example as low as 50°. Low values of the FoV enable proper focusing of the incident electromagnetic wave, irrespective of the distance between the source of the incident electromagnetic wave and the TMOS device 1.

For instance, the TMOS device 1 can be incorporated within a mobile device, for example a smartphone, for temperature detection.

The top coating 28 allows to increase the detection sensitivity of the TMOS device 1.

Consequently, the presence of the top coating 28 and the possibility of adjusting the distance h₂ bestow on the TMOS device 1 high detection performance and a high versatility for different applications.

FIGS. 2-17 show an embodiment of the process for manufacturing the TMOS device 1 of FIG. 1.

FIG. 2 shows a first cap wafer 60 of semiconductor material, for example silicon, having a first surface 60A and a second surface 60B.

The first cap wafer 60 is intended to form the cover substrate 21 of the cap 6 (FIG. 1).

Next, FIG. 3, a lithographic mask 61 is formed on the first surface 60A of the first cap wafer 60.

The lithographic mask 61 maybe formed by one or more polymeric layers and may be obtained via lithographic steps comprising deposition, exposure, for example to UV light or to an electron beam, and development of the one or more polymeric layers.

In detail, the one or more polymeric layers may be deposited via spin coating.

The lithographic mask 61 forms an opening 62 that exposes the portion of the first surface 60A of the first cap wafer 60 that is intended to form the inner wall 26 of the cover substrate 21.

Next, FIG. 4, a first coating region 64 is formed on the first cap wafer 60, by using the lithographic mask 61 as deposition mask.

The first coating region 64 may be formed by one or more layers arranged on top of one another, as described above for the top coating 28.

For instance, the first coating region 64 maybe formed via evaporation, sputtering, or other deposition processes.

The first coating region 64 comprises a central portion 64A, which extends within the opening 62 on the exposed portion of the first surface 60A, and a discard portion 64B, which extends over the mask 61.

The central portion 64A of the first coating region 64 forms the top coating 28 (FIG. 1).

Next, FIG. 5, the lithographic mask 61 is removed and the peripheral portion 64B of the first coating region 64 is also removed therewith.

Consequently, the central portion 64A of the first coating region 64 remains on the first surface 60A and forms the top coating 28.

In practice, the top coating 28 is formed via lift-off.

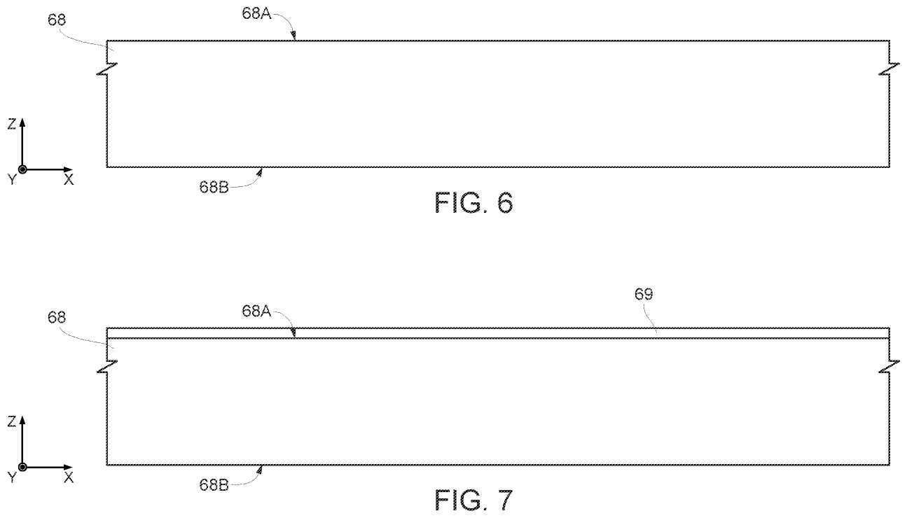

Separately, FIG. 6, a second cap wafer 68 of semiconductor material, for example of silicon, having a first surface 68A and a second surface 68B, is machined and is intended to form the supporting substrate 20 of the cap 6.

An insulating layer 69 is formed on the first surface 68A of the second cap wafer 68 (FIG. 7).

In detail, in this embodiment, the insulating layer 69 is a layer of oxide, for example silicon oxide, having a thickness along the third axis Z comprised, for example, between 0.5 μm and 2 μm.

The insulating layer 69 maybe deposited on the first surface 68A or else may be formed via oxidation of a surface portion of the second cap wafer 68.

The interface between the second cap wafer 68 and the insulating layer 69 is still referred to as the first surface 68A of the second cap wafer 68.

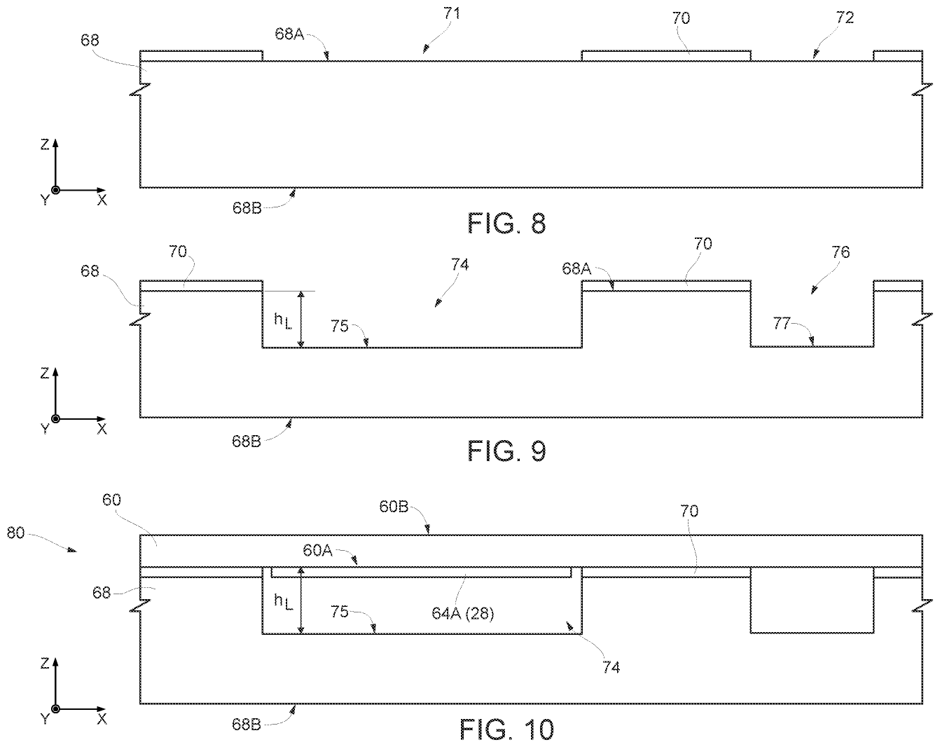

Next, FIG. 8, the insulating layer 69 is defined via lithographic and chemical etching steps.

Insulating portions 70 remain from the oxide layer 69, which are intended to form the third bonding region 22 (FIG. 1).

In detail, the insulating layer 69 is removed at the portions of the second cap wafer 68 where the top cavity 25 is to be formed, thus creating a corresponding work opening 71.

Furthermore, in this embodiment, the insulating layer 69 is removed also at the portions of the second cap wafer 68 where the opening 55 is to be formed, thus creating a corresponding work opening 72.

Then, FIG. 9, the second cap wafer 68 is chemically etched on the first surface 68A.

For instance, the insulating portions 70 maybe used as etching mask. However, a different etching mask may be formed on the first surface 68A.

Following upon the chemical etching, a recess 74 is formed in the second cap wafer 68, at the work opening 71.

The recess 74 is delimited by a bottom wall 75 of the second cap wafer 68.

Following upon the chemical etching, a recess 76 is also formed in the second cap wafer 68, at the work opening 72. The recess 76 is delimited by a bottom surface 77.

The recess 74 has a work height h_{L}, along the third axis Z, comprised for example between 40 μm and 200 μm, measured between the first surface 68A and the bottom surface 75.

In this embodiment, the recesses 74, 76 are formed simultaneously. However, the recesses 74, 76 may also be formed in distinct machining steps, for example if it is desired that the recesses 74, 76 have different heights.

Then, FIG. 10, the first cap wafer 60 and the second cap wafer 68 are bonded to one another to form a work cap 80.

In detail, the first surface 60A of the first cap wafer 60 is bonded on the insulating portions 70.

In particular, in this embodiment, the first and the second cap wafers 60, 68 are bonded via the fusion-bonding technique.

The second surface 68B of the second cap wafer 68 forms a surface, still indicated by 68B, of the work cap 80.

The recess 74 now forms a buried cavity in the work cap 80, delimited on a first side by the first surface 60A of the first cap wafer 60 and, on a second side opposite to the first side, by the bottom surface 75 of the second cap wafer 68.

The distance between the wall 75 of the second cap wafer 68 and the first surface 60A of the first cap wafer 60 is still indicated by h_{L}. In fact, the height of the buried cavity depends, to a first approximation, on the height of the recess 74, i.e., on the amount of material removed from the second cap wafer 68 in the step of FIG. 9. In fact, the thickness of the insulating layer 69 maybe much less than the height of the recess 74.

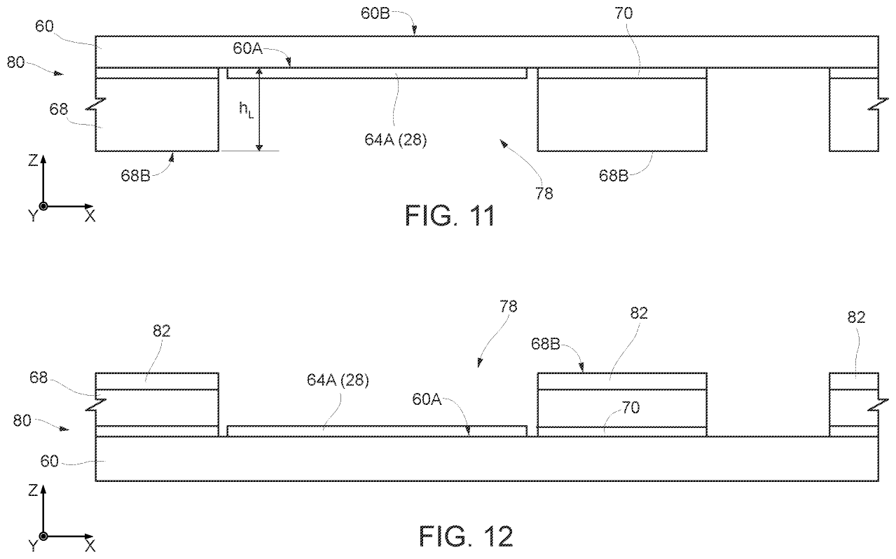

Next, FIG. 11, the work cap 80 is etched, starting from the second surface 68B, up to the bottom wall 75 of the second cap wafer 68. In practice, in FIG. 11, the recess 74 forms again an open cavity or opening, here indicated by 78.

In detail, the opening 78 is open on a side opposite to the first surface 60A of the first cap wafer 60.

The second surface of the remaining portions of the second cap wafer 68 is still indicated by 68B.

In this embodiment, the height h_{L} of the opening 78 remains substantially unchanged with respect to the height of the recess 74. However, etching of the second cap wafer 68B can be continued, even after reaching the bottom surface 75, so as to reduce the height of the opening 78.

In FIG. 12, a bonding layer 82, here made of glass frit, is formed on the second surface 68B of the remaining portions of the second cap wafer 68.

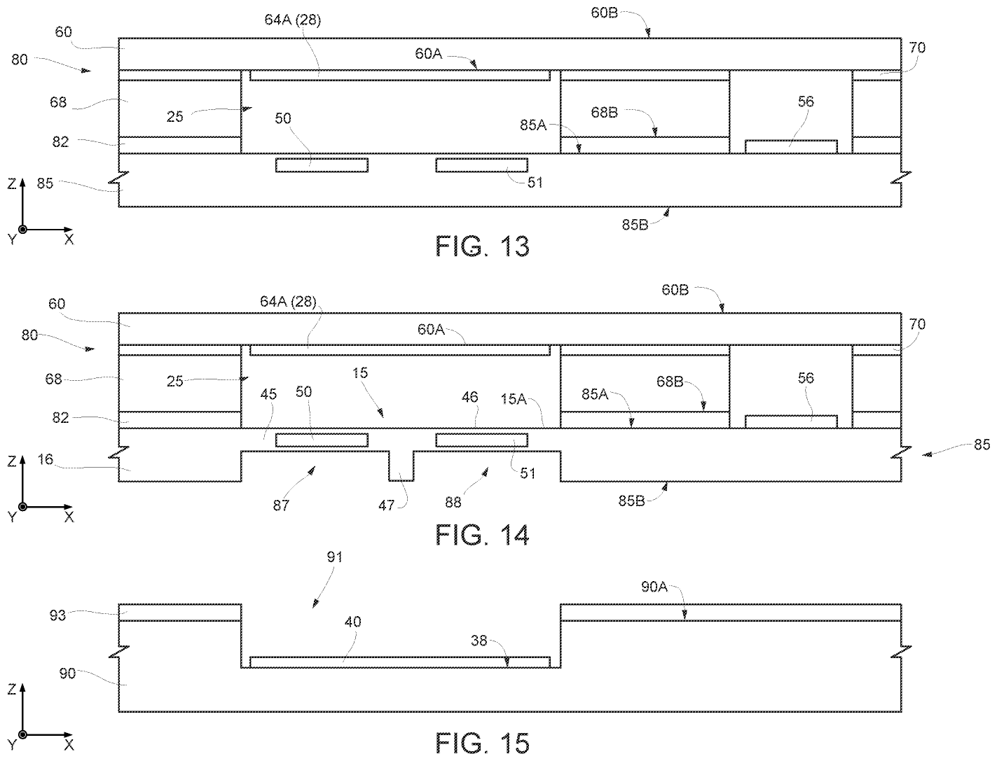

Next, FIG. 13, a device wafer 85 having a top surface 85A and a bottom surface 85B is bonded to the work cap 80.

In the device wafer 85, the sensitive regions 50, 51 have already been formed at the portion of wafer that is intended to form the functional structure 15.

In addition, on the top surface 85A of the device wafer 85 also the conductive pad 56 has been already formed.

In detail, the top surface 85A of the device wafer 85 is bonded to the work cap 80 via the bonding layer 82; the opening 78 thus forms the top cavity 25.

In detail, the device wafer 85 is bonded to the work cap 80 so that the top cavity 25 overlies the sensitive regions 50, 51.

In FIG. 14, the device wafer 85 is machined on the bottom surface 85B, for example via lithographic and chemical-etching steps, so as to form one or more bottom recesses, here a first bottom recess 87 and a second bottom recess 88, underneath the sensitive regions 50 and, respectively, 51.

With the formation of the first and the second bottom recesses 87, 88, the device wafer 85 may also be thinned out, according to the specific application.

In practice, with the formation of the first and the second bottom recesses 87, 88, the functional structure 15 is formed.

The first and the second bottom recesses 87, 88 extend, in a way here not illustrated, also through portions of the detection region 45 and, respectively, of the reference region 46, so as to allow, in the finished TMOS device 1, the top cavity 25 and the bottom cavity 35 (FIG. 1) to be in communication one with the other.

Separately, FIG. 15, a supporting wafer 90, here of semiconductor material, for example silicon, having a top surface 90A, is machined.

In the supporting wafer 90, a recess 91 has been formed; the recess 91 extends, from the top surface 90A, towards the inside of the supporting wafer 90, up to an inner surface corresponding to the inner wall 38 (FIG. 1) and thus indicated by the same reference number.

Furthermore, the bottom coating 40 has been formed on the inner surface 38. For instance, the bottom coating 40 maybe formed via deposition, evaporation, sputtering, or other per se known deposition processes.

A bonding layer 93, for example of glass frit, is formed on the top surface 90A of the supporting wafer 90.

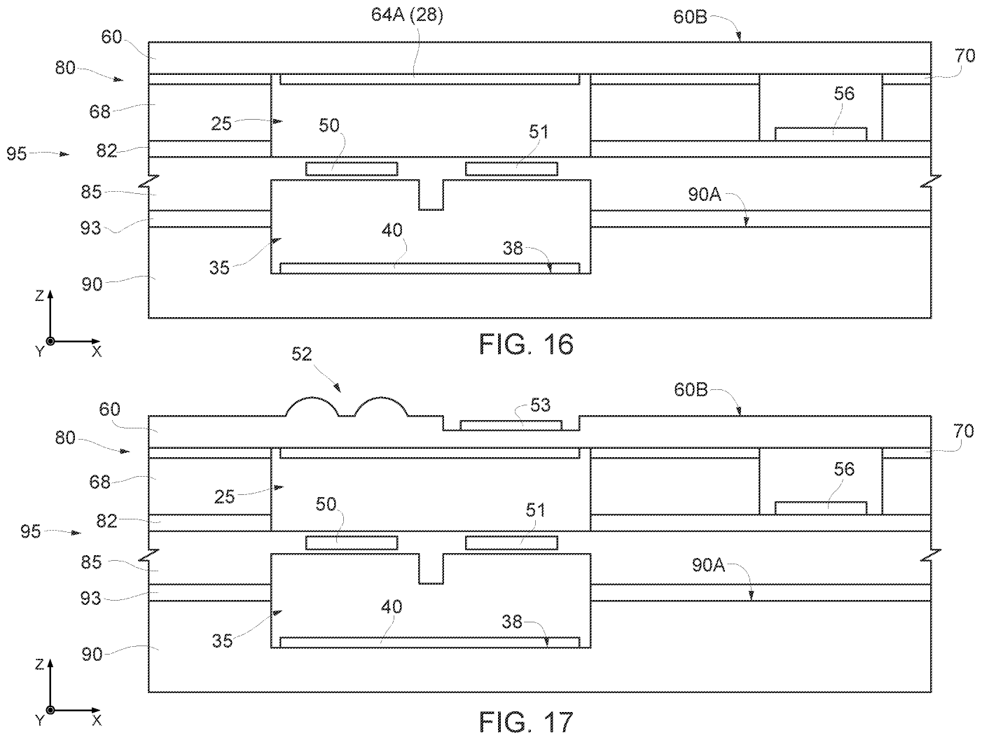

Next, FIG. 16, the supporting wafer 90 is bonded to the device wafer 85 using the bonding layer 93, thus forming a composite body 95 comprising the work cap 80, the device wafer 85 and the supporting wafer 90.

In detail, the top surface 90A of the supporting wafer 90 is bonded to the back surface 85B of the device wafer 85 so that the recess 91 of the supporting wafer 90 faces the functional structure 15. In practice, the bottom cavity 35 is thus formed.

The second surface 60B of the first cap wafer 60 forms a top surface of the composite body 95, which is still indicated by 60B.

Next, FIG. 17, the lenses 52 and the shielding region 53 are formed on the top surface 60B of the composite body 95 in a per se known way.

Further manufacturing steps, not illustrated herein, then follow, such as formation of the contact opening 55 and dicing of the composite body 95, which lead to formation of the TMOS device 1 of FIG. 1.

The fact that the cap 6 is formed by machining two separate wafers (first and second cap wafers 60, 68) allows the top coating 28 and the top cavity 25 to be formed independently of one another.

In other words, the steps that lead to formation of the top coating 28 are not affected by the steps that lead to definition of the height h₂ (FIG. 1).

This bestows on the present manufacturing process both a large freedom to choose, at the design stage, the value of the height h₂, for example to obtain large values of the height h₂, in particular greater than 40 μm, and the possibility of simplifying formation of the top coating 28.

In fact, formation of the top coating 28 within a deep recess, for example deeper than 40 μm, could make the formation of the lithographic mask 61 and, consequently, also the formation of the top coating 28, to be problematic.

Instead, the possibility of forming the top coating 28 on the first surface 68A may enable to use a lift-off process for forming the top coating 28 and, for example, the spin-coating technique for forming the lithographic mask 61, irrespective of the value of the height h₂.

This allows to simplify the process for manufacturing the TMOS device 1 and, at the same time, allows to adapt the properties of the TMOS device 1, at the design stage, according to the specific application. For instance, the corresponding TMOS device 1 maybe used in applications in which it is desired both that the height h₂ is great (greater than 40 μm), for example in order to obtain a small field of view, for example as low as 50°, and to obtain a high detection sensitivity thanks to the presence of the top coating 28.

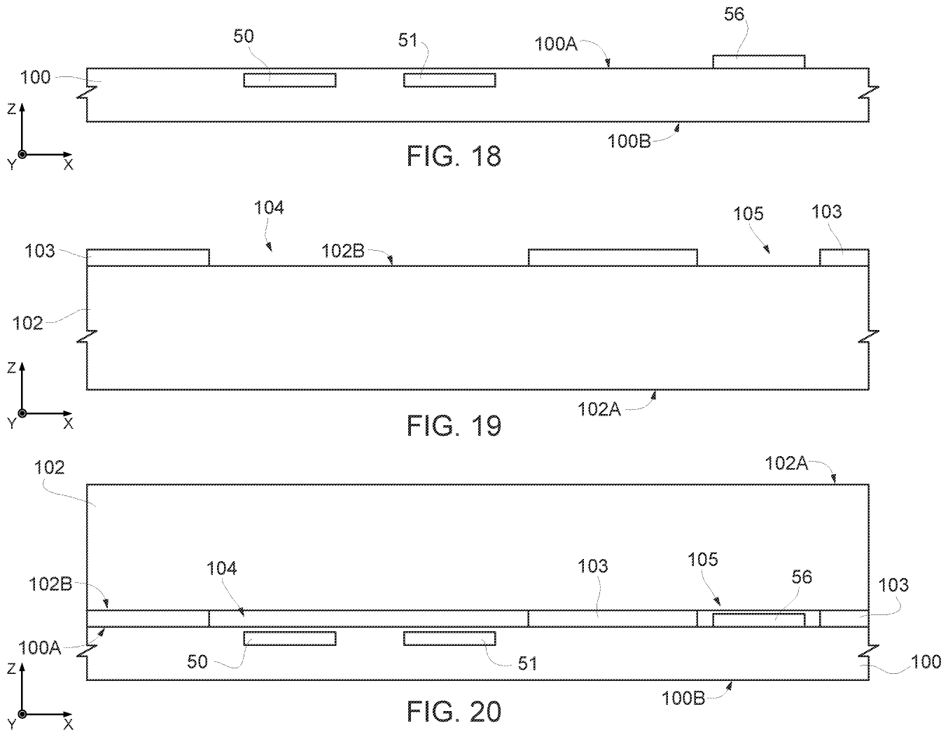

FIGS. 18-25 show a different embodiment of the process for manufacturing the TMOS device 1 of FIG. 1.

FIG. 18 shows a device wafer, here indicated by 100, having a top surface 100A and a bottom surface 100B that is bonded to the work cap 80.

In the device wafer 100, the sensitive regions 50, 51 have already been formed at the portion of wafer that is intended to form the functional structure 15.

Furthermore, also the conductive pad 56 has already been formed on the top surface 100A of the device wafer 100.

Separately, FIG. 19, the second cap wafer is machined; the second cap wafer, here designated by 102, is intended to form the supporting substrate 20 (FIG. 1), is of semiconductor material, for example silicon, and has a first surface 102A and a second surface 102B.

A bonding layer of insulating material, for example glass frit, comprising portions 103 delimiting work openings 104, 105, is formed on the second surface 102B of the second cap wafer 102.

The work opening 104 exposes a portion of the second cap wafer 102 where the top cavity 25 is intended to be formed.

The work opening 105 exposes a portion of the second cap wafer 102 where the contact opening 55 (FIG. 1) is intended to be formed.

Next, FIG. 20, the second cap wafer 102 is bonded to the top surface 100A of the device wafer 100, by using the portions 103.

In detail, the second cap wafer 102 is bonded to the device wafer 100 in such a way that the work openings 104, 105 overlie the sensitive regions 50, 51 and, respectively, the conductive pad 56.

Following upon bonding, the portions 103 have a thickness, along the third axis Z, comprised for example between 5 μm and 20 μm.

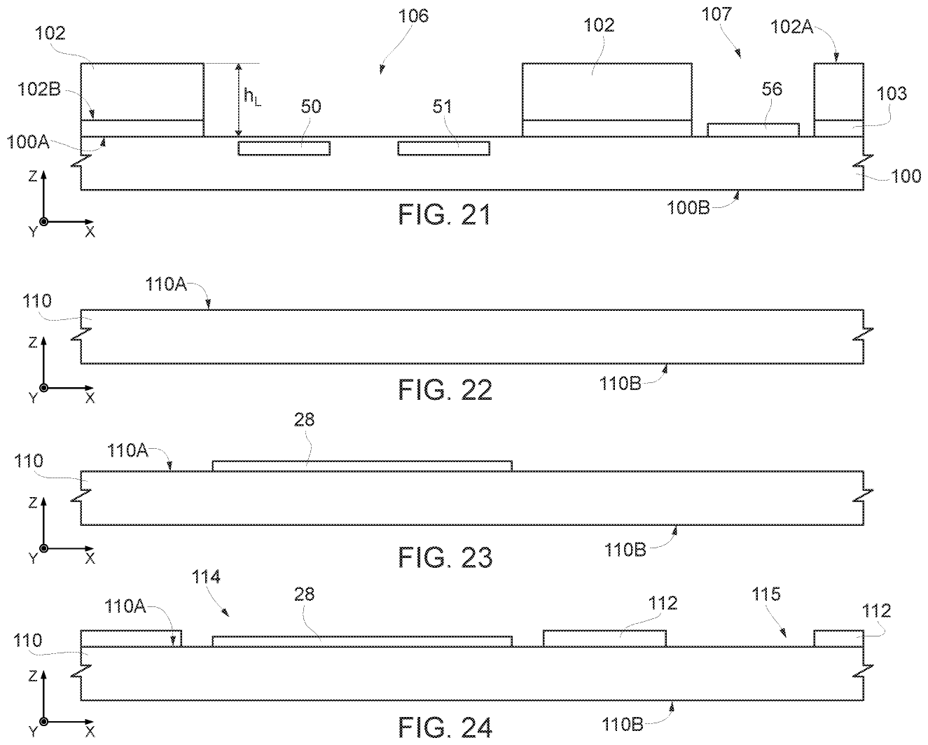

In FIG. 21, the second cap wafer 102 is selectively etched on the top surface 102A so as to remove portions of the second cap wafer 102 at the work openings 104, 105, thereby forming openings indicated by 106, 107.

In practice, the openings 106, 107 extend through the second cap wafer 102, thus exposing portions of the device wafer 100 at the sensitive regions 50, 51 and, respectively, at the conductive pad 56.

From the second cap wafer 102 thus remain portions, still indicated by 102, which delimit the openings 107, 108 laterally.

Following upon etching, the distance h_{L} between the top surface 102A and the surface 100A of the device wafer 100 may be comprised between 40 μm and 200 μm.

For instance, the second cap wafer 102 can undergo lapping on the top surface 102A and subsequent chemical etching, or just selective chemical etching on the top surface 102A, according to the desired value of the distance h_{L} .

Separately, FIG. 22, the first cap wafer, which is intended to form the cover substrate 21 (FIG. 1) and is here indicated by 110, is machined. The first cap wafer 110 has a first surface 110A and a second surface 110B.

In FIG. 23, the top coating 28 is formed on the first surface 110A of the first cap wafer 110, as described with reference to FIGS. 3-5.

Next, FIG. 24, a bonding layer 112, for example of insulating material, in particular here of glass frit, is formed on the surface 110A of the device wafer 110. The bonding layer 112 is defined so as to extend on a side of the top coating 28.

In practice, the bonding layer 112 forms an opening 114. The top coating 28 extends within the opening 114.

The bonding layer 112 also forms an opening 115 where the contact opening 55 is intended to be formed (FIG. 1).

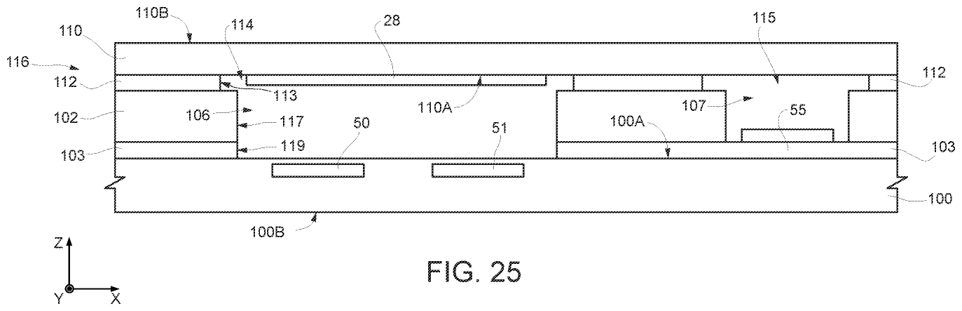

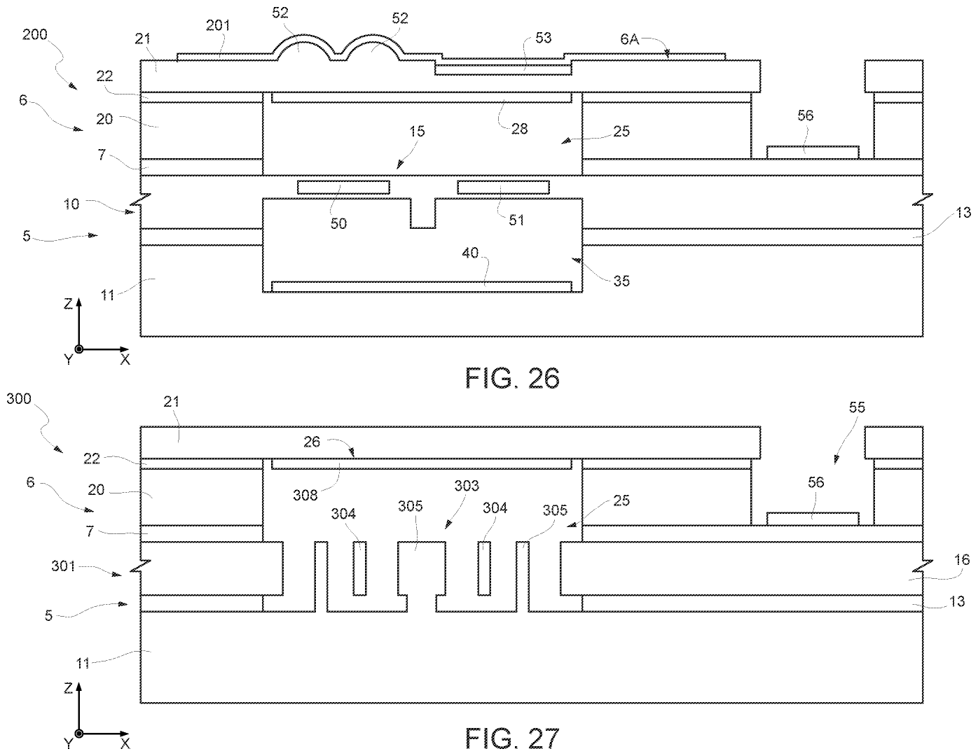

In FIG. 25, the first cap wafer 110 is bonded to the second cap wafer 102 using the bonding layer 112; a composite body 116 is thus formed. As shown in FIG. 25, in some embodiments, the bonding layer 112 has respective sidewalls 113 spaced outward from respective sidewalls 117 of the second cap wafer 102 and respective sidewalls 119 of the portions 103. Alternatively, as shown in some of the other Figures of the present disclosure (e.g., at least FIGS. 26 and 27), the respective sidewalls 113 may be coplanar with the respective sidewalls 117, 119.

In practice, the openings 106, 114 form a cavity corresponding to the top cavity 25 of the TMOS device 1. The openings 107, 115 form a cavity that is intended to form the contact opening 55 of the TMOS device 1.

Next, the device wafer 110 undergoes machining steps that lead to the definition of the functional structure 15, as described with reference to FIG. 14.

Moreover, the composite body 116 is further machined, as described with reference to FIGS. 15-17.

Also in this embodiment, the separate machining of the first and the second cap wafers 110, 102 bestows a high versatility of design of the TMOS device 1, in particular of the height h₂ of the top cavity 25, as discussed for the manufacturing process described with reference to FIGS. 2-17.

Finally, it is clear that modifications and variations may be made to the present MEMS device and to the present manufacturing process described and illustrated herein, without thereby departing from the scope of the present disclosure, as defined in the annexed claims.

For instance, FIG. 26 shows a different embodiment of the TMOS device, here indicated by 200, having a general structure that is the same as that of the TMOS device 1 of FIG. 1; consequently, elements in common are indicated by the same reference numbers and are not described any further.

In detail, the TMOS device 200 differs from the TMOS device 1 in so far as it further comprises an external coating 201, also here of the antireflective type, for example formed by the same materials that form the top coating 28. The external coating 201 extends on the top surface 6A of the cap 6.

In detail, in this embodiment, the external coating 201 extends also on the lenses 52 and on the shielding region 53.

The coating 201 allows to increase further the detection sensitivity of the present TMOS device.

For instance, the active regions 50, 51 maybe based upon elements sensitive to infrared radiation that are different, not obtained through the TMOS technology. For instance, the active regions 50, 51 maybe thermopiles based upon the Seebeck effect.

Alternatively, the present MEMS device may be a different device, where the functional structure can be configured to transduce a physical quantity different from the infrared radiation, or to transduce a chemical quantity into a corresponding electrical quantity.

For instance, FIG. 27 shows a further embodiment of the present MEMS device, here indicated by 300, wherein the MEMS device 300 is an inertial sensor, for example an accelerometer or a gyroscope.

The MEMS device 300 has a general structure similar to that of the TMOS device 1; consequently, elements in common are indicated by the same reference numbers and are not described any further.

The MEMS device 300 comprises a device substrate, here indicated by 301, comprising the peripheral structure 16 and a functional structure, here indicated by 303.

The MEMS device 300 comprises a cavity, which forms a hermetic chamber 302.

The functional structure 303, of a per se known type, is configured to generate one or more electrical signals in response to a movement of the MEMS device 300, for example an acceleration or a rotation.

For instance, the functional structure 303 may be configured to operate according to a transduction mechanism of electrostatic type, piezoelectric type, piezoresistive type, etc.

For instance, in the embodiment illustrated, the functional structure 303, here illustrated only schematically, is based upon a capacitive transduction mechanism. In detail, the functional structure 303 is suspended in the chamber 302 and comprises mobile electrodes 304, coupled in a way here not illustrated to the peripheral structure 16, and stator electrodes 305 fixed to the supporting substrate 11.

The MEMS device 300 comprises also here a top coating, indicated by 308, extending within the chamber 302 on the inner wall 26 of the cover substrate 21. The top coating 308 may be a single-layer or multilayer region, for example a getter coating, similar to what has been discussed for the bottom coating 40 of the TMOS device 1 of FIG. 1.

It will be clear to the person skilled in the art that the manufacturing processes described with reference to FIGS. 2-17 and 18-25 can be adapted also to form the MEMS devices 200, 300 of FIGS. 26, 27.

According to a different embodiment, the lenses 52 of the TMOS devices 1, 200 may be lenses of a type different from what has been illustrated, for example made of polymeric material or resins that are totally or partially transparent to infrared radiation. Alternatively, the TMOS devices 1, 200 may be without lenses.

For instance, with reference to the MEMS device 1 of FIG. 1, the bottom cavity 35 and the top cavity 25 maybe isolated from one another, i.e., separated from one another by the functional structure 15, according to the specific application.

For instance, the functional structure 15 may comprise only one sensitive region; in this case, the TMOS device 1 does not comprise the shielding region 53.

For instance, the supporting substrate 20 and the cover substrate 21 of the cap 6 may be made of a different material, for example glass.

For instance, the steps of the manufacturing process may be performed in an order different from what has been illustrated in FIGS. 2-17 and 18-25.

For instance, with reference to FIGS. 3 and 4, a recess having a small depth along the third axis Z, for example less than 40 μm, may be formed in the first cap wafer 60, at the opening 62 before forming the first coating region 64. In this way, it may be possible to have a further degree of freedom for defining the height h₂.

Finally, the embodiments described may be combined to provide further solutions.

A MEMS device (1; 200; 300) may be summarized as including: a sensor body (5) including a functional structure (15; 303) configured to transduce a physical or chemical quantity into a corresponding electrical quantity; a cap (6) bonded to the sensor body and having a first cavity (25) overlying the functional structure, wherein the cap includes a supporting portion (20, 22) and a cover portion (21) that form the first cavity, the supporting portion being bonded to the sensor body, the cover portion being bonded to the supporting portion and having an inner wall (26) delimiting on a side the first cavity and facing the functional structure; and a first coating (28) extending within the first cavity on the inner wall of the cover portion.

The supporting portion of the cap may include a supporting substrate (21) bonded to the sensor body, and a cap bonding region (22) extending between the supporting substrate and the cover portion and may include a layer of oxide or of glass frit.

The supporting portion (20, 22) of the cap may laterally delimit the first cavity (25).

The functional structure (15; 303) may have a surface (15A) facing the inner wall (26) and extending at a distance greater than 40 μm from the inner wall.

The sensor body may include a device substrate (10; 301) and a support substrate (11), wherein the device substrate may include the functional structure and a peripheral structure (16) coupled to the functional structure and having a first surface (10A) and a second surface (10B) opposite to the first surface, the cap (6) being bonded to the first surface of the peripheral structure, the support substrate (11) being bonded to the second surface (10B) of the peripheral structure (16).

The first coating (28) may be an antireflective coating or a getter coating.

The sensor body (5) may have a second cavity (35) arranged on an opposite side of the functional structure (15; 303) with respect to the first cavity, the functional structure being suspended in the first cavity and the second cavity.

The sensor body may have an inner wall (38) delimiting on a side the second cavity and facing the functional structure, the MEMS device may further include a second coating (40) extending on the inner wall of the sensor body.

The second coating (40; 310) may be an antireflective coating or a getter coating.

The functional structure (15) may include at least one active region (50, 51) sensitive to an incident infrared radiation and the first coating (28) is an antireflective layer.

A process for manufacturing a MEMS device, may be summarized as including: forming, in a device wafer (85; 100), a functional structure (15; 303) configured to transduce a physical or chemical quantity into a corresponding electrical quantity; and forming a cap (6) starting from a first cap wafer (60; 110) and a second cap wafer (68; 102), wherein forming a cap includes: forming a first coating (28) on a surface (60A; 110A) of the first cap wafer; forming an opening (78;

106) in the second cap wafer; bonding the second cap wafer to the device wafer; and bonding the first cap wafer to the second cap wafer, so that the opening (78; 106) forms a first cavity that overlies the functional structure and the surface (60A; 110A) of the first cap wafer forms an inner wall (26) of the cap that delimits on a side the first cavity and faces the functional structure.

The step of forming a first coating may be performed before bonding the first cap wafer (60; 110) to the second cap wafer (68; 102).

The first coating may be formed via lift-off.

The step of bonding the first cap wafer (110) to the second cap wafer (102) may be performed after the step of bonding the second cap wafer (102) to the device wafer (100) and after the step of forming an opening (106) in the second cap wafer.

Forming an opening (78) in the second cap wafer (68) may include: before bonding the first cap wafer to the second cap wafer, forming a recess (74) in the second cap wafer starting from a first surface (68A) of the second cap wafer, the recess being delimited by a bottom wall (75) of the second cap wafer; and after the step of bonding the second cap wafer to the first cap wafer, etching the second cap wafer (68) from a second surface (68B) of the second cap wafer opposite to the first surface, up to the bottom wall (75).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device comprising:
a sensor body including a functional structure configured to transduce a physical or chemical quantity into a corresponding electrical quantity, the functional structure including:
a first surface;
a second surface opposite to the first surface;
a first thickness that extends from the first surface to the second surface;
a reference region including a first sensitive region, the reference region has the first thickness;
a detection region including a second sensitive region, the detection region having the first thickness;
a coupling region couples together the reference region to the detection region, the coupling region has an end surface spaced apart from the second surface, and the coupling region includes a second thickness that extends from the first surface to the end surface, the second thickness being greater than the first thickness;
a cap bonded to the sensor body and having a first cavity overlying the functional structure, wherein the cap comprises a supporting portion and a cover portion that form the first cavity, the supporting portion being bonded to the sensor body, the cover portion being bonded to the supporting portion and having an inner wall delimiting on a side the first cavity and facing the functional structure; and
a first coating extending within the first cavity on the inner wall of the cover portion.

2. The device according to claim 1, wherein the supporting portion of the cap comprises a supporting substrate bonded to the sensor body, and a cap bonding region extending between the supporting substrate and the cover portion and comprising a layer of oxide or of glass frit.

3. The device according to claim 1, wherein the supporting portion of the cap laterally delimits the first cavity.

4. The device according to claim 1, wherein the functional structure has a surface facing the inner wall and extending at a distance greater than 40 μm from the inner wall.

5. The device according to claim 1, wherein the sensor body comprises a device substrate and a support substrate, wherein the device substrate comprises the functional structure and a peripheral structure coupled to the functional structure and having a first surface and a second surface opposite to the first surface, the cap being bonded to the first surface of the peripheral structure, the support substrate being bonded to the second surface of the peripheral structure.

6. The device according to claim 1, wherein the first coating is an antireflective coating or a getter coating.

7. The device according to claim 1, wherein the sensor body has a second cavity arranged on an opposite side of the functional structure with respect to the first cavity, the functional structure being suspended in the first cavity and the second cavity.

8. The device according to claim 7, wherein the sensor body has an inner wall delimiting on a side the second cavity and facing the functional structure, the MEMS device further comprising a second coating extending on the inner wall of the sensor body.

9. The device according to claim 8, wherein the second coating is an antireflective coating or a getter coating.

10. The device according to claim 1, wherein the first coating is an antireflective layer.

11. A method, comprising:
forming, in a device wafer, a functional structure configured to transduce a physical or chemical quantity into a corresponding electrical quantity; and
forming a cap starting from a first cap wafer and a second cap wafer,
wherein forming a cap comprises:
forming a first coating on a surface of the first cap wafer;
forming an opening in the second cap wafer;
bonding the second cap wafer to the device wafer; and
bonding the first cap wafer to the second cap wafer,
so that the opening forms a first cavity that overlies the functional structure and the surface of the first cap wafer forms an inner wall of the cap that delimits on a side the first cavity and faces the functional structure.

12. The method according to claim 11, wherein the step of forming a first coating is performed before bonding the first cap wafer to the second cap wafer.

13. The method according to claim 11, wherein the first coating is formed via lift-off.

14. The method according to claim 11, wherein the step of bonding the first cap wafer to the second cap wafer is performed after the step of bonding the second cap wafer to the device wafer and after the step of forming an opening in the second cap wafer.

15. The method according to claim 11, wherein forming an opening in the second cap wafer comprises:
before bonding the first cap wafer to the second cap wafer, forming a recess in the second cap wafer starting from a first surface of the second cap wafer, the recess being delimited by a bottom wall of the second cap wafer; and
after the step of bonding the second cap wafer to the first cap wafer, etching the second cap wafer from a second surface of the second cap wafer opposite to the first surface, up to the bottom wall.

16. A device, comprising:
a sensor body including:
a first cavity within the sensor body;
a functional structure suspended over the first cavity, the functional structure including:
a first surface;
a second surface opposite to the first surface;
a first thickness that extends from the first surface to the second surface;
a reference region including a first sensitive region, the reference region has the first thickness;
a detection region including a second sensitive region, the detection region having the first thickness;
a coupling region couples together the reference region to the detection region, the coupling region has an end surface spaced apart from the second surface, and the coupling region includes a second thickness that extends from the first surface to the end surface, the second thickness being greater than the first thickness;
a cap coupled to the sensor body, the cap including:
at least one lens that overlaps the second sensitive region of the detection region; and
a shielding region that overlaps the first sensitive region of the reference region.

17. The device of claim 16, wherein the cap further includes a second cavity overlapping the functional structure.

18. The device of claim 17, wherein the cap further includes:
a surface that delimits the second cavity, overlaps the functional structure, faces the functional structure, and is spaced apart from the functional structure; and
an antireflective coating region on the surface of the cap.

19. The device of claim 18, wherein the antireflective coating region fully overlaps the first sensitive region of the reference region and fully overlaps the second sensitive region of the detection region.

20. The device of claim 18, wherein sensor body further includes:
a surface that delimits the first cavity, is overlapped by the functional structure, faces the functional structure, and is spaced apart from the functional structure; and
a getter region on the surface of the sensor body.
